(19) United States
(12) Patent Application Publication
(10) Pub. No.: US 2026/0062286 A1
(43) Pub. Date: Mar. 5, 2026

(54) MULTI-CHIP SENSOR

(71) Applicant: Infineon Technologies AG, Neubiberg (DE)

(72) Inventors: Klaus ELIAN, Alteglofsheim (DE); Horst THEUSS, Wenzenbach (DE); Matthias EBERL, Taufkirchen (DE)

(21) Appl. No.: 19/296,594

(22) Filed: Aug. 11, 2025

(30) Foreign Application Priority Data
Aug. 29, 2024 (DE) 102024208231.7

(51) Int. Cl. B81B 7/00; B81B 7/02; B81C 1/00; G01L 9/00; G01N 19/10

(52) U.S. Cl. CPC B81B 7/0061; B81B 7/0074; B81B 7/02; B81C 1/00309; G01L 9/0042; B81B 2201/0214; B81B 2201/0264; B81B 2207/07; G01N 19/10

(57) ABSTRACT

A sensor device includes a first sensor die arranged on a base element, a second sensor die arranged on the base element or on a first top surface of the first sensor die. The sensor device further includes an encapsulation material covering a part of the base element and surrounding the first sensor die and the second sensor die such that the first top surface is covered by the encapsulation material and at least a portion of a second top surface of the second sensor die is uncovered by the encapsulation material.

### CROSS REFERENCE TO RELATED APPLICATION

This application claims priority to Germany Patent Application No. 102024208231.7 filed on Aug. 29, 2024, the content of which is incorporated by reference herein in its entirety.

### TECHNICAL FIELD

The present disclosure relates to a multi-chip sensor and to a method for forming such a sensor.

### BACKGROUND

Integrated multi-chip sensors typically comprise a base element, such as a substrate or a semiconductor chip, with a plurality of sensor devices arranged on a surface thereof. For example, environmental sensors include multiple sensor devices for measuring various environmental parameters such as air pressure, temperature, humidity, or gas compositions. While such multi-chip sensors exist in the consumer area, automotive applications, such as fuel cell monitoring, thermal runaway detection or battery failure detection, for instance, are characterized by specific requirements concerning protection, reliability, and longevity. For conventional sensor devices, this protection can be achieved by employing the so-called “glob-top” packaging method, according to which a glob or drop of resin is arranged on a surface of the base element such that substrate, sensor device and bond wires are covered and thus protected.

As environmental sensors, such as humidity or concentration sensors, generally require an opening towards an environment of the sensor, the glob-top method cannot be applied as sensitive surfaces of the sensor must remain uncovered.

### SUMMARY

The problem to be solved by the present disclosure is therefore to provide a multi-chip sensor characterized by sufficient protection of susceptible surfaces and elements, wherein a sensing surface remains in contact with an environment.

The problem is solved by the sensor device and the method according to the independent claims.

In an implementation, the sensor device includes a base element, and a first sensor die arranged on the base element, wherein the first sensor die has a first top surface facing away from the base element. The sensor device further includes a second sensor die that is arranged on the base element or on a first portion of the first top surface, wherein the second sensor die has a second top surface facing away from the base element. The sensor device further includes an encapsulation material that surrounds a part of the base element, the first sensor die and the second sensor die such that the first top surface is covered by the encapsulation material and at least a portion of the second top surface is uncovered by the encapsulation material.

Accordingly, a method for forming a sensor device includes arranging a first sensor die on a base element, wherein the first sensor die has a first top surface facing away from the base element. The method further includes arranging a second sensor die on the base element or on a first portion of the first top surface, wherein the second sensor die has a second top surface facing away from the base element. The method further includes surrounding part of the base element, the first sensor die and the second sensor die with a encapsulation material such that the first top surface is covered by the encapsulation material and at least a portion of the second top surface is uncovered by the encapsulation material.

Thus, a multi-chip sensor is provided, wherein at least one of the sensor chips is fully surrounded by a encapsulation material, or a glob, while at least one other sensor chip is surrounded by the encapsulation material in a manner such that a sensitive sensing surface is left uncovered. For example, the first sensor chip includes means for sensing pressure, which can be performed through a encapsulation material covering the sensitive surface, while the second sensor chip is a humidity sensor, for example, requiring an exposed sensing surface to the environment.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a first example a sensor device according to one or more implementations.

FIG. 2 illustrates a second example a sensor device according to one or more implementations.

FIG. 3 illustrates a third example a sensor device according to one or more implementations.

FIG. 4 illustrates a fourth example a sensor device according to one or more implementations.

FIG. 5 is a flowchart of an example process associated with forming a sensor device.

### DETAILED DESCRIPTION

In the following, details are set forth to provide a more thorough explanation of example implementations. However, it will be apparent to those skilled in the art that these implementations may be practiced without these specific details. In other instances, well-known structures and devices are shown in block diagram form or in a schematic view, rather than in detail, in order to avoid obscuring the implementations. In addition, features of the different implementations described hereinafter may be combined with each other, unless specifically noted otherwise.

Further, equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually interchangeable.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “top,” “bottom,” “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling (e.g., any connection or coupling without additional intervening elements) may also be implemented by an indirect connection or coupling (e.g., a connection or coupling with one or more additional intervening elements, or vice versa) as long as the general purpose of the connection or coupling (e.g., to transmit a certain kind of signal or to transmit a certain kind of information) is essentially maintained. Features from different implementations may be combined to form further implementations. For example, variations or modifications described with respect to one of the implementations may also be applicable to other implementations unless noted to the contrary.

As used herein, the terms “substantially” and “approximately” mean “within reasonable tolerances of manufacturing and measurement. ” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, a signal with an approximate signal value may practically have a signal value within 5% of the approximate signal value.

In the present disclosure, expressions including ordinal numbers, such as “first”, “second”, and/or the like, may modify various elements. However, such elements are not limited by such expressions. For example, such expressions do not limit the sequence and/or importance of the elements. Instead, such expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

A “sensor” may refer to a component which converts a property to be measured to an electrical signal (e.g., a current signal or a voltage signal). The property to be measured may, for example, comprise a magnetic field, an electric field, an electromagnetic wave (e.g., a radio wave), a pressure, a force, a current, or a voltage, but is not limited thereto. A gas sensor may measure a property of a gas, such as a thermal conductivity of the gas. Based on the measured property, a presence of the gas can be detected. Additionally, based on the measured property, a concentration of the gas can be measured.

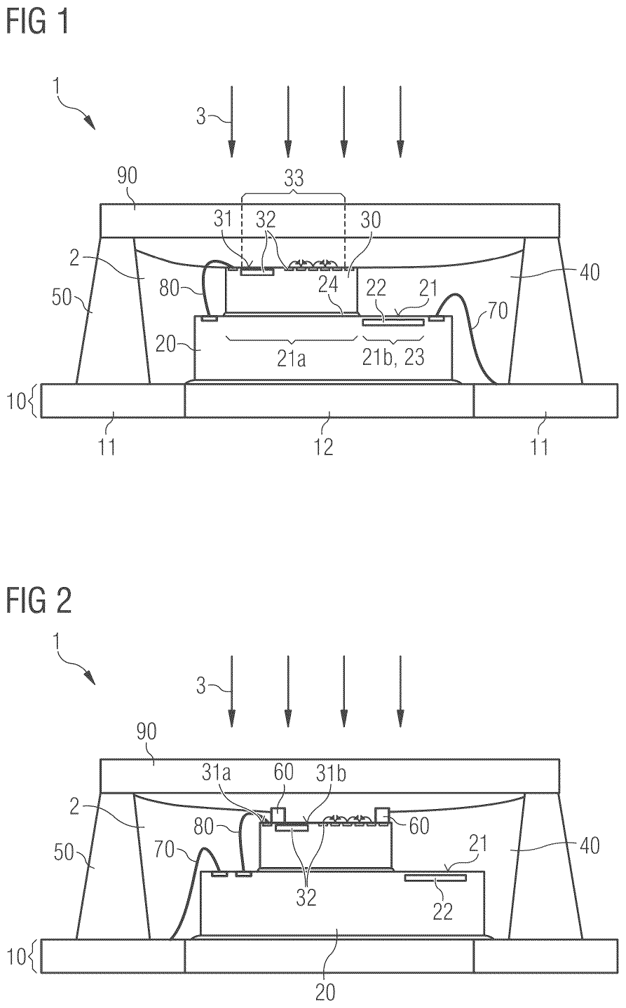

FIG. 1 illustrates a sensor device 1 according to one or more implementations. The sensor device 1 comprises a base element 10, for example, a semiconductor substrate body such as a silicon chip. The base element 10 can comprise a leadframe section 11 for mechanically mounting and/or electrically connecting the sensor device 1 to a printed circuit board, for instance. Alternatively, or in addition, the base element 10 comprises at least one of a substrate, a printed circuit board, a leadframe, a plastic element or a ceramic element. Within a substrate portion 12 of the base element 10, a first sensor die 20, e.g., a sensor chip, is arranged on a top surface of the base element 10. The first sensor die 20 has a first top surface 21 that faces away from the base element 10. At or within the first top surface 21 of the first sensor die 20, a first sensor structure 22 is arranged in a first sensing portion 23 of the first top surface 21. The first sensor structure 22 may be a micro-electro-mechanical systems (MEMS) pressure sensor with a MEMS diaphragm covering and hermitically sealing a cavity underneath the membrane, wherein a deflection of the MEMS diaphragm is indicative of a pressure acting onto a top surface of the MEMS diaphragm. For example, the first sensor structure 22 may be configured to measure a pressure acting on the first sensing portion 23 of the first top surface 21 based on a measurement signal.

The sensor device 1 in this example implementation further comprises a second sensor die 30 that is arranged on the first top surface 21 of the first sensor die 20. More precisely, the second sensor die 30 is arranged on a first portion 21a of the first top surface 21 different from the first sensing portion 23. In other words, the first top surface 21 is separated into a first portion 21a and a second portion 21b different from and adjacent to the first portion 21a, wherein the second sensor die 30 is arranged within the first portion 21a and the first sensing portion 23 is arranged within or coincides with the second portion 21b. The first sensor die 20 and the second sensor die 30 form a sensor stack that is arranged on the base element 10.

The second sensor die 30 has a second top surface 31 that faces away from the base element 10 and from the first top surface 21 of the first sensor die 20. At or within the second top surface 31 of the second sensor die 30, a second sensor structure 32 is arranged in a second sensing portion 33 of the second top surface 31. The second sensor structure 32 may be a gas sensor structure and comprise one or more sensing elements, e.g., gas sensing elements. For example, the second sensor structure 32 comprises a thermal conductivity (TC) sensor that measures a thermal conductivity of gas that is in contact with the second sensing portion 33 of the second top surface 31 to measure a concentration of the gas. For example, a sensing element of the second sensor structure 32 may be configured to measure a thermal conductivity of the measurement gas based on a measurement signal and determine the concentration of the target gas based on the thermal conductivity of the measurement gas.

Alternatively, or in addition, the second sensor structure 32 can comprise a humidity sensing element configured to measure an absolute or relative humidity of gas that is in contact with the second sensing portion 33 of the second top surface 31.

The sensor device 1 further comprises a first bond wire 70 interconnecting an electrically conductive part of the base element 10, e.g., a first bond pad or a leadframe section 11, with an electrically conductive portion of the first top surface 21, e.g., a second bond pad. Similarly, the sensor device 1 further comprises a second bond wire 80 interconnecting an electrically conductive portion of the first top surface 21, e.g., a third bond pad, with an electrically conductive portion of the second top surface 31, e.g., a fourth bond pad. The first bond wire 70, the second bond wire 80 and optional further bond wires enable an operation of the first and second sensor structures 22, 32 via the leadframe section 11, for instance.

As indicated in the figure, the first sensor die 20 can comprise a protective coating 24 that is arranged within the first portion 21a of the first top surface 21 and serve as an intermediate layer, on which the second sensor die 30 is arranged. Within the first portion 21a, the first top surface 21 can be understood as a top surface of the protective coating 24.

The sensor device 1 further comprises a sidewall element 50 arranged on the base element and surrounding, e.g., fully surrounding in a lateral direction, the first sensor die 20 and the second sensor die 30 in a manner to define, together with the base element 10, a trough-like space 2, in which the first sensor die 20 and the second sensor die 30 are arranged. For example, a height of the sidewall element 50 is larger than a height of the sensor stack formed by the first sensor die 20 and the second sensor die 30. A top side of the sensor device, acting as an inlet port 3, can be open to an environment or be covered by a protective membrane 90 that is permeable for gas, e.g., permeable for a target gas that is to be measured by the sensor device 1. The protective membrane 90 can be arranged on a top surface of the sidewall element 50 as illustrated. The sidewall element 50 and the optional protective membrane 90 can form a leaded or non-leaded package defining the space 2 as a cavity.

The sensor device further comprises an encapsulation material 40, e.g., a glob top or a gel, in particular a fluorine-free gel, that is filled into the space 2 in a manner such that the first sensor die 20 is fully surrounded by the encapsulation material 40, e.g., sidewalls and the first top surface 21 are covered by the encapsulation material 40, and the second sensor die 30 is surrounded such that the second top surface 31 is left uncovered by the encapsulation material 40. The encapsulation material 40 can be a material characterized by a Young's modulus of less than 50 MPa at an ambient temperature, for instance. In particular, the second sensing portion 33 of the second sensor structure 32 is uncovered by the encapsulation material 40. The encapsulation material 40 provides protection against particles and chemical impact by covering the base element 10 in between the sidewall element 50, the first sensor die 20, the first bond wire 70 and a portion of the second bond wire 80 and second sensor die 30. Furthermore, the encapsulation material 40 can provide mechanical stability for the bond wires 70, 80 and the bonding to bond pads, for instance.

FIG. 2 illustrates a further sensor device 1 according to one or more implementations. Compared to the implementation according to FIG. 1, the sensor device 1 according to this implementation further comprises a blocking structure 60 that is arranged on the second top surface 31 in a manner such that the second top surface 31 is segmented into a first region 31a and a second region 31b. For example, the blocking structure 60 forms a ring-like structure surrounding the second region 31b that comprises the second sensing portion 33, for instance, leaving the second region 31b outside of the blocking structure 60. The blocking structure 60 can be formed from a polyimide or an epoxy, for instance.

In consequence to the blocking structure 60 dividing the second top surface 31 into a first region 31a and a second region 31b, the encapsulation material 40 can fill the space 2 defined by the sidewall element 50 and the base element 10 in a manner such that the first region 31a is covered by the encapsulation material 40, while the second region 31b comprising the second sensing portion 33 of the second sensor structure 32 remains uncovered by the encapsulation material 40. In other words, the blocking structure 60 prevents the encapsulation material 40 from covering the second region 31a. In yet other words the blocking structure 60 is not fully covered by the encapsulation material 40 as it extends beyond a top level of the encapsulation material 40 in a vertical direction with respect to the second top surface 31.

Thus, the implementation of FIG. 2 allows for a filling of the space 2 with the encapsulation material 40 to a level that is above the second top surface 31 but below a top surface of the blocking structure 60 as illustrated. This way, the second bond wire 80, can likewise be fully surrounded by the encapsulation material 40, including its bonding points to the second top surface 31 that comprises a bond pad, for instance.

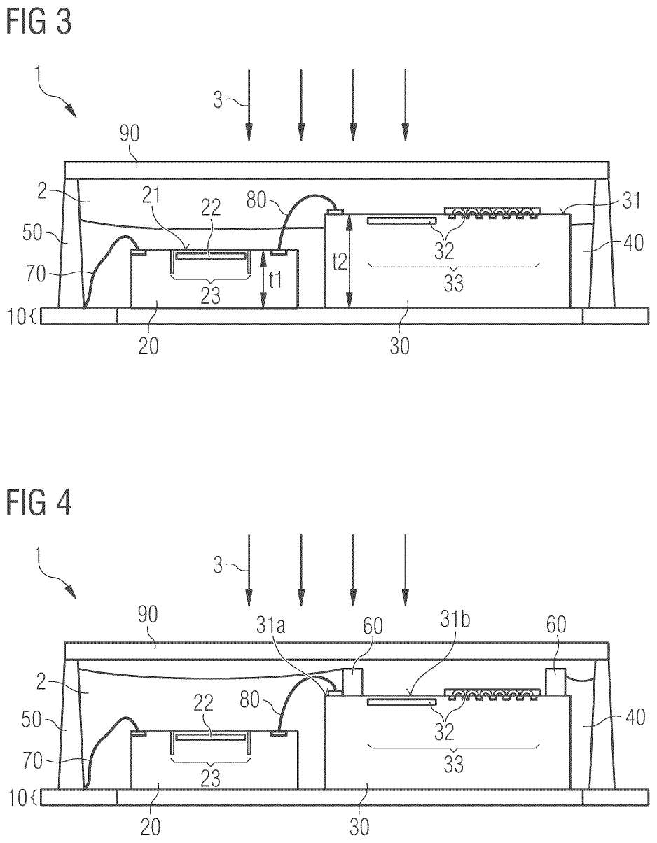

FIG. 3 illustrates a further sensor device 1 according to one or more implementations. In this implementation, the second sensor die 30 is arranged on the base element 10 next to the first sensor die 20. The second sensor die 30 can be arranged immediately adjacent to the first sensor die 20 or in a certain distance forming a gap in between as illustrated. Analogous to the implementations of FIGS. 1 and 2, the encapsulation material 40 during manufacturing is filled into the space 2 defined by the base element 10 and the sidewall element 50 in a manner such that the first sensor die 20 is fully covered by the encapsulation material 40, while the second top surface 31 of the second sensor die 30 is uncovered by the encapsulation material 40. This can be achieved by a thickness t1 of the first sensor die 20 being less than the thickness t2 of the second sensor die 30.

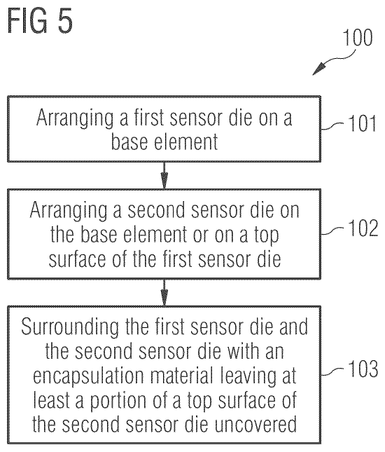

FIG. 4 illustrates a further sensor device 1 according to one or more implementations. Compared to the implementation according to FIG. 3, the sensor device 1 according to this implementation further comprises a blocking structure 60 like that introduced with the implementation of FIG. 2. The blocking structure 60 enables a larger amount of encapsulation material 40 in the space 2 for entirely covering the second bond wire and the bond pad it is bonded to in the first region 31a of the second top surface 31, for instance.

FIG. 5 is a flowchart of an example process associated with manufacturing a sensor device according to one of the implementations. The manufacturing method comprises a first step 101 of arranging a first sensor die 20 on a base element 10, wherein the first sensor die 20 has a first top surface 21 facing away from the base element 10. The method further comprises a second step 102 of arranging a second sensor die 30 on the base element 10 or on a first portion 21a of the first top surface 21, wherein the second sensor die 30 has a second top surface 31 facing away from the base element 10. The method further comprises a third step 103 of covering part of the base element 10 and surrounding the first sensor die 20 and the second sensor die 30 with an encapsulation material 40 such that the first top surface 21 is covered by the encapsulation material 40 and at least a portion of the second top surface 31 is uncovered by the encapsulation material 40.

The present disclosure is especially well suited for multi-chip environmental sensors, such as humidity sensors temperature sensors and gas concentration sensors, whose sensor elements are required to be uncovered by any encapsulation such as a glob top or an encapsulating gel, while at the same time including sensors like pressure sensors which can be fully encapsulated. The present disclosure can also be applied to optical sensors, flow sensors or other sensor types.

Although specific examples have been illustrated and described herein, it will be appreciated by those of ordinary skill in the art that a variety of alternate and/or equivalent implementations may be substituted for the specific examples shown and described without departing from the scope of the present implementation. This application is intended to cover any adaptations or variations of the specific examples discussed herein. Therefore, it is intended that this implementation be limited only by the claims and the equivalents thereof.

It should be noted that the methods and devices including its preferred implementations as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the implementation and are included within its spirit and scope. Furthermore, all examples and implementations outlined in the present document are principally intended expressly to be only for explanatory purposes to help the reader in understanding the principles of the proposed methods and systems. Furthermore, all statements herein providing principles, aspects, and implementations of the implementation, as well as specific examples thereof, are intended to encompass equivalents thereof.

### ASPECTS

The following provides an overview of some Aspects of the present disclosure:

Aspect 1: A sensor device, comprising: a base element; a first sensor die arranged on the base element, the first sensor die having a first top surface facing away from the base element; a second sensor die arranged on the base element or on a first portion of the first top surface, the second sensor die having a second top surface facing away from the base element; and an encapsulation material covering a part of the base element and surrounding the first sensor die and the second sensor die such that the first top surface is covered by the encapsulation material and at least a portion of the second top surface is uncovered by the encapsulation material.

Aspect 2: The sensor device of Aspect 1, wherein the base element comprises at least one of a substrate, a printed circuit board, a leadframe, a plastic element, or a ceramic element.

Aspect 3: The sensor device of any of Aspects 1-2, wherein the first sensor die comprises a first sensor structure arranged in a first sensing portion of the first top surface, wherein the first sensing portion is covered by the encapsulation material.

Aspect 4: The sensor device of Aspect 3, wherein the first sensor structure comprises a micro-electro-mechanical systems (MEMS) pressure sensor.

Aspect 5: The sensor device of any of Aspects 1-4, wherein the second sensor die comprises a second sensor structure arranged in a second sensing portion of the second top surface, wherein the second sensing portion is uncovered by the encapsulation material.

Aspect 6: The sensor device of Aspect 5, wherein the second sensor structure comprises a gas sensor and/or a humidity sensor.

Aspect 7: The sensor device of any of Aspects 1-6, further comprising: a sidewall element provided on the base element surrounding the first sensor die and the second sensor die, wherein the encapsulation material is filled in a space defined by the sidewall element and the base element.

Aspect 8: The sensor device of any of Aspects 1-7, wherein the second sensor die is arranged on the base element next to the first sensor die.

Aspect 9: The sensor device of Aspect 8, wherein the first top surface of the first sensor die is fully covered by the encapsulation material.

Aspect 10: The sensor device of Aspect 8, wherein a thickness of the first sensor die is less than a thickness of the second sensor die.

Aspect 11: The sensor device of any of Aspects 1-10, wherein the second sensor die is arranged on the first portion of the first top surface.

Aspect 12: The sensor device of Aspect 11, wherein a second portion of the first top surface, in particular a first sensing portion, different from the first portion is fully covered by the encapsulation material.

Aspect 13: The sensor device of any of Aspects 1-12, wherein the first sensor die comprises a protective coating, and the first top surface comprises a top surface of the protective coating.

Aspect 14: The sensor device of any of Aspects 1-13, further comprising: a blocking structure arranged on the second top surface separating the second top surface into a first region; and a second region, wherein the encapsulation material covers the first region, and the second region is uncovered by the encapsulation material.

Aspect 15: The sensor device of any of Aspects 1-14, further comprising: a first bond wire electrically coupling the first sensor die to the base element, wherein the first bond wire is fully covered by the encapsulation material.

Aspect 16: The sensor device of any of Aspects 1-15, further comprising: a second bond wire electrically coupling the second sensor die to the first sensor die or to the base element, wherein the second bond wire is at least partially covered by the encapsulation material.

Aspect 17: The sensor device of Aspect 16, wherein the second bond wire is fully covered by the encapsulation material.

Aspect 18: The sensor device of Aspect 1, further comprising: a protective membrane covering an inlet port of the sensor device, wherein the protective membrane is permeable to gas.

Aspect 19: The sensor device of Aspect 1, wherein the encapsulation material is a glob top or a fluorine-free gel, and/or comprises silicone.

Aspect 20: A method for forming a sensor device, the method comprising: arranging a first sensor die on a base element, the first sensor die having a first top surface facing away from the base element; arranging a second sensor die on the base element or on a first portion of the first top surface, the second sensor die having a second top surface facing away from the base element; and covering part of the base element and surrounding the first sensor die and the second sensor die with an encapsulation material such that the first top surface is covered by the encapsulation material and at least a portion of the second top surface is uncovered by the encapsulation material.

Aspect 21: A system configured to perform one or more operations recited in one or more of Aspects 1-20.

Aspect 22: An apparatus comprising means for performing one or more operations recited in one or more of Aspects 1-20.

### REFERENCE NUMERALS

1 sensor device
2 space
3 inlet
10 base element
11 leadframe section
12 substrate portion
20, 30 sensor die
21, 31 top surface
21a, 21b portion
22, 32 sensor structure
23, 33 sensing portion
24 protective coating
31a, 31b region
40 encapsulation material
50 sidewall element
60 blocking structure
70, 80 bond wire
90 protective membrane
t1, t2 thickness

1. A sensor device (1), comprising:
a base element (10),
a first sensor die (20) arranged on the base element (10), the first sensor die (20) having a first top surface (21) facing away from the base element (10),
a second sensor die (30) arranged on the base element (10) or on a first portion (21a) of the first top surface (21), the second sensor die (30) having a second top surface (31) facing away from the base element (10),
an encapsulation material (40) covering a part of the base element (10) and surrounding the first sensor die (20) and the second sensor die (30) such that the first top surface (21) is covered by the encapsulation material (40) and at least a portion of the second top surface (31) is uncovered by the encapsulation material (40).

1. The sensor device (1) of claim 1, wherein the base element (10) comprises at least one of a substrate, a printed circuit board, a leadframe, a plastic element or a ceramic element.

2. The sensor device (1) of claim 1 or 2, wherein the first sensor die (20) comprises a first sensor structure (22) arranged in a first sensing portion (23) of the first top surface (21), wherein the first sensing portion (23) is covered by the encapsulation material (40).

3. The sensor device (1) of claim 3, wherein the first sensor structure (22) comprises a MEMS sensor, in particular a MEMS pressure sensor.

4. The sensor device (1) of any one of claims 1 to 4, wherein the second sensor die (30) comprises a second sensor structure (32) arranged in a second sensing portion (33) of the second top surface (31), wherein the second sensing portion (33) is uncovered by the encapsulation material (40).

5. The sensor device (1) of claim 5, wherein the second sensor structure (32) comprises a gas sensor and/or a humidity sensor.

6. The sensor device (1) of any one of claims 1 to 6, further comprising a sidewall element (50) provided on the base element (10) surrounding the first sensor die (20) and the second sensor die (30), wherein the encapsulation material (40) is filled in a space (2) defined by the sidewall element (50) and the base element (10).

7. The sensor device (1) of any one of claims 1 to 7, wherein the second sensor die (30) is arranged on the base element (10) next to the first sensor die (20).

8. The sensor device (1) of claim 8, wherein the first top surface (21) of the first sensor die (20) is fully covered by the encapsulation material (40).

9. The sensor device (1) of claim 8 or 9, wherein a thickness (t1) of the first sensor die (20) is less than the thickness (t2) of the second sensor die (30).

10. The sensor device (1) of any one of claims 1 to 7, wherein the second sensor die (30) is arranged on the first portion (21a) of the first top surface (21).

11. The sensor device (1) of claim 11, wherein a second portion (21b) of the first top surface (21), in particular a first sensing portion (23), different from the first portion (21a) is fully covered by the encapsulation material (40).

12. The sensor device (1) of any one of claims 1 to 12, wherein the first sensor die (20) comprises a protective coating (24) and the first top surface (21) comprises a top surface of the protective coating (24).

13. The sensor device (1) of any one of claims 1 to 13, further comprising a blocking structure (60) arranged on the second top surface (31) separating the second top surface (31) into a first region (31a) and a second region (31b), wherein the encapsulation material (40) covers the first region (31a), and the second region (31b) is uncovered by the encapsulation material (40).

14. The sensor device (1) of any one of claims 1 to 14, further comprising a first bond wire (70) electrically coupling the first sensor die (20) to the base element (10), wherein the first bond wire (70) is fully covered by the encapsulation material (40).

15. The sensor device (1) of any one of claims 1 to 15, further comprising a second bond wire (80) electrically coupling the second sensor die (30) to the first sensor die (20) or to the base element (10), wherein the second bond wire (80) is at least partially covered by the encapsulation material (40).

16. The sensor device (1) of claim 16, wherein the second bond wire (80) is fully covered by the encapsulation material (40).

17. The sensor device (1) of any one of claims 1 to 17, further comprising a protective membrane (90) covering an inlet port (3) of the sensor device (1), wherein the protective membrane (90) is permeable to gas.

18. The sensor device (1) of any of claims 1 to 18, wherein the encapsulation material (40) is a glob top or a gel, in particular a fluorine-free gel, and/or comprises silicone.

19. A method for forming a sensor device (1), the method comprising:
arranging a first sensor die (20) on a base element (10), the first sensor die (20) having a first top surface (21) facing away from the base element (10),
arranging a second sensor die (30) on the base element (10) or on a first portion (21a) of the first top surface (21), the second sensor die (30) having a second top surface (31) facing away from the base element (10),
covering part of the base element (10) and surrounding the first sensor die (20) and the second sensor die (30) with an encapsulation material (40) such that the first top surface (21) is covered by the encapsulation material (40) and at least a portion of the second top surface (31) is uncovered by the encapsulation material (40).
